(19) United States
(12) Patent Application Publication
(10) Pub. No.: US 2005/0161820 A1
(43) Pub. Date: Jul. 28, 2005

(54) Integrated circuit with conductive grid for power distribution

(76) Inventor: Ravindraraj Ramaraju, Round Rock, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/765,810

(22) Filed: Jan. 27, 2004

(51) Int. Cl. H01L 23/48

(52) U.S. Cl. 257/758

(57) ABSTRACT

A grid for a power supply distribution of cells of circuits has a plurality of subgrids in which each subgrid has continuous lines across it. Each line has an unchanging width but the widths of the lines vary from each other. The lines on the perimeter are the thickest and each line is thinner than the previous line until the middle is reached. Thus, the line or lines in the middle are the thinnest. This provides both good uniformity in supply voltage and efficient interconnect.

### FIELD OF THE INVENTION

This invention relates to integrated circuits, and more particularly, to semiconductor devices that use a conductive grid for distribution of power to the active circuits.

### RELATED ART

In many designs for integrated circuits, many of the various elements are in a standard cell format and some as custom cells. For example an operational circuit such as a shift register or a NOR gate may be available to the designer with an existing layout and interconnect scheme. The locations for the inputs, outputs, and power connections are predetermined. The designer, which may in fact be a team of individuals, then makes a design to achieve an overall functional objective using the various standard cells and custom cells connected in a manner needed to achieve this functional objective.

One of the difficulties of this approach has been ensuring that the interface between the various cells is effective, in particular that the outputs are at the needed voltage level for the cells that are receiving them. In order to ensure that the needed cell-to-cell voltage compatibility is achieved, it is desirable for all of the cells to receive the same power supply voltage and thus be operating at the same voltage levels. This can be difficult to achieve because the distance that the supply current must travel is not the same for the different cells. This can result in different voltage drops in the power lines for the various cells resulting in the cells receiving different voltages as the power supply. While the uniform power supply voltage is desirable, it is also desirable to be able to interconnect the various cells in an efficient manner.

Thus, there is a need for providing power supply scheme that provides needed uniformity while also providing efficient utilization of the space available for providing functional interconnection between the cells.

### BRIEF DESCRIPTION OF THE DRAWINGS

The present invention is illustrated by way of example and not limited by the accompanying figures, in which like references indicate similar elements, and in which:

FIG. 1 is a cross section of a device according to a first embodiment of the invention;

FIG. 2 is a top view showing more detail of a first portion of the device of FIG. 1 according to the first embodiment of the invention; and

FIG. 3 is a top showing more detail of a second portion of the device of FIG. 2 according to the second embodiment of the invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one aspect a grid for a power supply distribution of cells of circuits has a plurality of subgrids in which each subgrid has continuous lines across it. Each line has an unchanging width but the widths of the lines vary from each other. The lines on the perimeter are the thickest and each line is thinner than the previous line until the middle is reached. Thus, the line or lines in the middle are the thinnest. This provides both good uniformity in supply voltage and efficient interconnect.

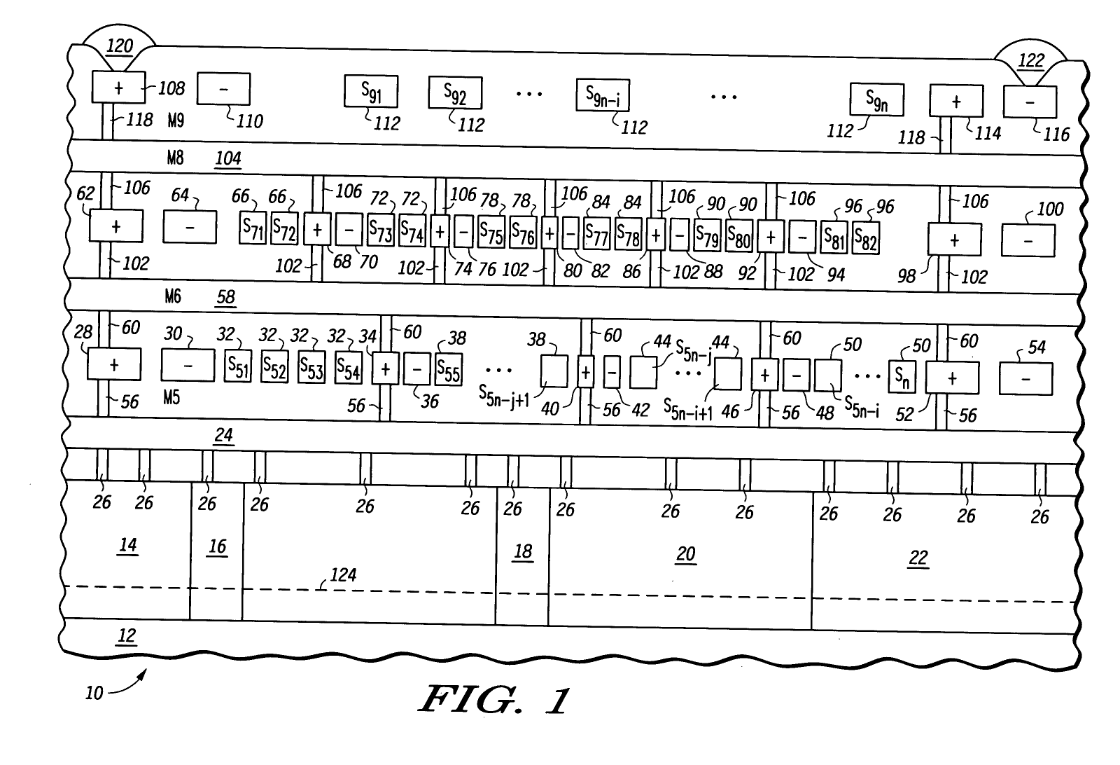

Shown in FIG. 1 is a semiconductor device 10 comprising a semiconductor substrate 12, cells 14, 16, 18, 20 and 22 in and over substrate 12 that provide various circuit functions; a conductive line 24 over cells 14-22; vias 26 connecting cells 14-22 to conductive line 24; over metal line 24 a conductive line 28 as a positive power supply (+) line such as VDD, a conductive line 30 as a negative power supply (−) line such as ground, a positive power supply line 34, a plurality of signal lines 32 between supply lines 30 and 34, a negative supply line 36, a positive supply line 40, a plurality of signal lines 38 between supply lines 36 and 40, a negative supply line 42, a positive supply line 46, a plurality of signal lines 44 between supply lines 42 and 46, a negative power supply line 48, a positive power supply line 52, and a plurality of signal lines 50, and a negative power supply line 54; a plurality of vias 56, which are known to be conductive, connecting positive power supply lines 28, 36, 40, 46, and 52 to conductive line 24; conductive line 58; a plurality of vias 60 connecting positive power supply lines 28, 34, 40, 46, and 52 to conductive line 58; over conductive line 58 a positive power supply line 62, a negative power supply line 64, a positive power supply line 68, a plurality of signal lines 66 between supply lines 64 and 68, a negative power supply line 70, a positive power supply line 74, a plurality of signal lines 72 between supply lines 70 and 74, a negative power supply line 76; a positive power supply line 80, a plurality of signal lines 78 between supply lines 76 and 80, a negative power supply line 82, a positive power supply line 86, a plurality of signal lines 84 between supply lines 82 and 86, a negative power supply line 88, a positive power supply line 92, a plurality of signal lines 90 between supply lines 88 and 92, a negative power supply line 94, a positive power supply line 98, a plurality of signal lines 96 between supply lines 94 and 98, and a negative power supply line 100; a plurality of vias connecting positive power supply lines 62, 68, 74, 80, 86, 92, and 98 to conductive line 58; a conductive line 104 above lines 62-100; a plurality of vias 106 connecting supply lines 62, 68, 74, 80, 86, 92, and 98 to conductive line 104; a positive power supply line 108; a negative power supply line 110; a positive power supply line 114; a plurality of signal lines 112 between supply lines 110 and 114; a negative power supply line 116; a bump 120 connected positive power supply line 108; and a bump 122 connected to negative power supply line 116.

Cells 14-22 have portion in substrate 12 and a portion above substrate 12. Line 124 shows the substrate. Cells 14-22 provide functions chosen by a designer and include transistors and an interconnect that connects those transistors in a manner to achieve to the function. The transistors are mostly formed in substrate 12 and may have a portion, such as gates, above the substrate. Most if not all of the interconnection of the transistors is in the portion above the substrate. Cells 14-22 receive power and are interconnected to each other by metal layers above cells 14-22. In this example, there are three levels of metal in the cells above the substrate and six metal layers above the cells for providing connections to the cells. Each metal layer above cells 14-22 contains both signal lines and power supply lines. The lines in a given metal layer generally run all in the same direction. Adjacent layers run in directions orthogonal to each other. That characteristic is common for integrated circuits that utilize cells. Conductive line 24 is the only line shown in FIG. 1 in the fourth metal layer, which is the first metal layer above the cells in this example. Conductive line 24 in this example is for carrying the positive power supply voltage. Lines 28-54 are in the fifth metal layer and run orthogonal to line 24. Pluralities of signal lines 32, 38, 44, and 50 carrying signals to and from the standard cells. Signals can logic signals, amplified signals, clock signals, or any other signal useful in achieving circuit functions. Conductive line 58 is in the sixth metal layer and in this example is for carrying the positive power supply voltage. Lines 62-100 are in the seventh metal layer. Line 104 is in the eighth metal layer. Lines 108-116 are in the ninth metal layer. The various metal layers are separated by dielectric and the lines within a given metal layer are similarly separated. Of course many more lines are present in all of the metal layers than those shown.

With regard to power supply lines 62, 64, 68, 70, 74, 76, 80, 82, 86, 88, 92, 94, 98, and 100 of the Bumps 120 and 122 are for making electrical connection outside of device 10 such as to a printed circuit board or an integrated circuit package. As previously stated the fourth through ninth metal layers are for interconnecting the cells, providing external signals to the cells, providing outputs from the cells, and providing a power supply voltage to the cells. These metal layers contain both signals and power supply lines. The power supply lines in adjacent metal layers run orthogonal to each other. With regard to power supply lines 62, 64, 68, 70, 74, 76, 80, 82, 86, 88, 92, 94, 98, and 100 of the seventh metal layer, the width of these lines are progressively narrower as the middle between lines 62 and 100 is approached. Lines 62 and 100 are the widest. An example of such a width is about 10 microns. The lines are progressively less wide by about one third. In this example then, the width of line 92 is one third less than the width of line 98, the width of line 86 is one third less than the width of line 92, the width of line 80 is one third less than the width of lines 74 and 86, the width of line 74 is one third less than the width of line 68, and the width of line 68 is one third less than the width of line 62. This same width reduction is also true for the sixth metal layer. The fourth and fifth metal layers also have reduced width as the middle between bumps 120 and 122 is reached.

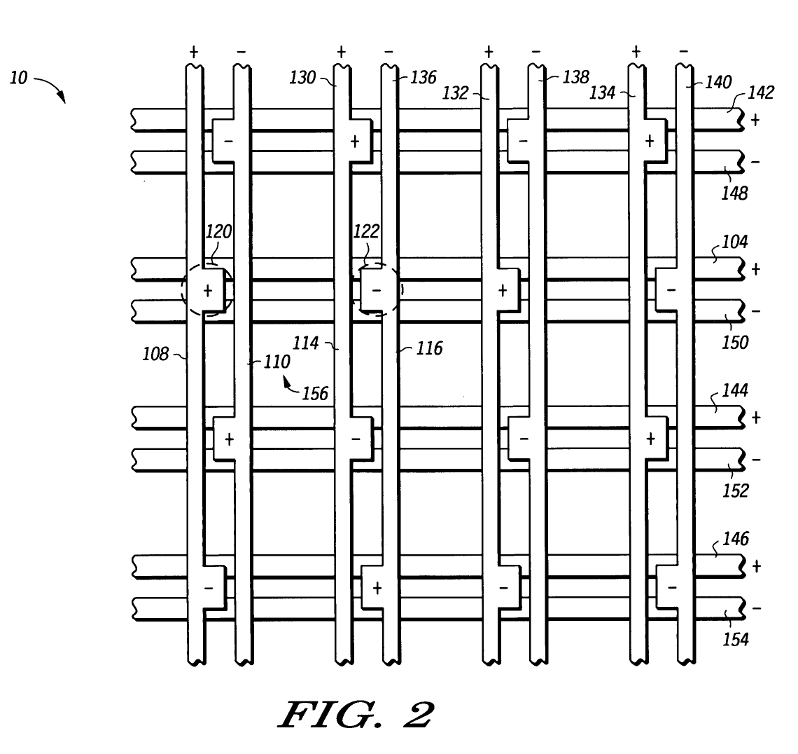

Shown in FIG. 2 is a portion of device 10 showing detailed portions of the eighth and ninth metal layers. The lines present in both FIG. 1 and FIG. 2 are lines 108, 110, and 104. Also shown in both of these figures is the location of bumps 120 and 122. Further shown in FIG. 2 are positive power supply lines 130, 132, and 134 present in the ninth metal layer; negative power supply lines 136, 138, and 140 present in the ninth metal layer; positive power supply lines 142 present in the eighth metal layer, 144, and 146; and negative power supply lines 148, 150, 152, and 154 in the eighth metal layer. All of these lines extend across substantially the whole integrated circuit and form a grid. At the periphery of the integrated circuit is where most of the signal connections are made. Adjacent positive and negative power supply lines form pair lines that run together and define subgrids. For example lines 108 and 110 form a first pair, lines 130 and 136 a second pair, lines 104 and 150 form a third pair, and lines 144 and 152 a fourth pair. The area between the intersections of these four pairs forms a subgrid 156. In FIG. 2 then there are shown nine subgrids such as subgrid 156. Within subgrid 156 is a plurality of additional power supply lines that become increasing thinner toward the center of subgrid 156.

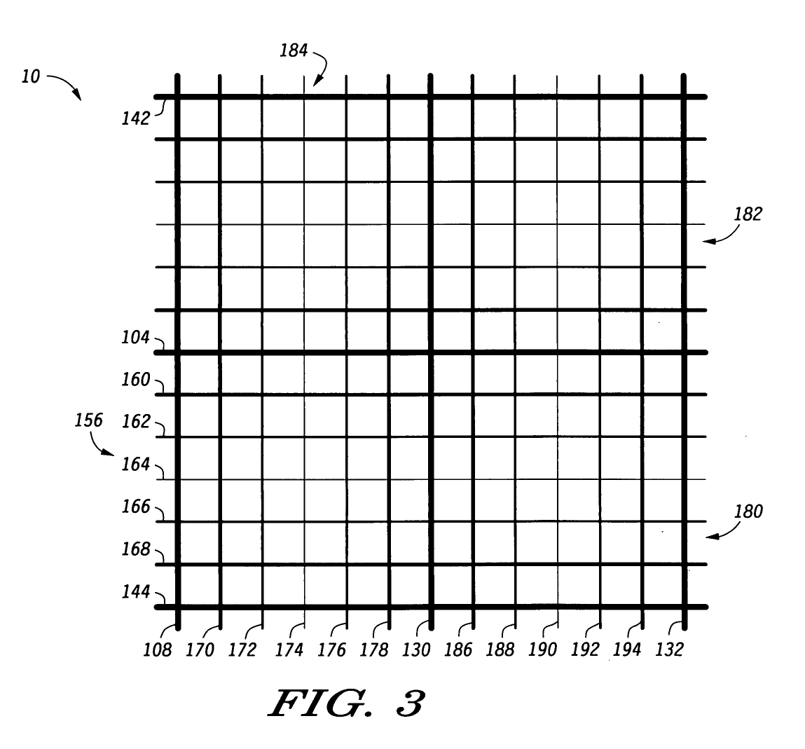

Shown in FIG. 3 is a positive power supply portion of subgrid 156 as well as three other subgrids showing the additional power supply lines of the positive power supply voltage. For subgrid 156 the additional power supply lines shown for the eighth metal layer, which run horizontally in FIG. 3, are lines 160, 162, 164, 166, and 168. Line 160 is adjacent to line 104 and is less wide than line 104. Line 168 is adjacent to line 144 and is less wide than line 144. Line 162 is adjacent to line 160 and is less wide than line 160. Line 166 is adjacent to line 168 and is less wide than line 168. Line 164 is spaced from and is between lines 162 and 166 and is less wide than lines 162 and 166. Similarly for grid 156, the additional power supply lines shown for the ninth layer, which run vertically in FIG. 3, are lines 170, 172, 174, 176, and 178. Line 170 is adjacent to line 108 and is less wide than line 108. Line 178 is adjacent to line 130 and is less wide than line 130. Line 172 is adjacent to line 170 and is less wide than line 170. Line 176 is adjacent to line 178 and is less wide than line 178. Line 174 is between lines 172 and 176 and is less wide than lines 172 and 176.

Line 164 is the positive power supply line formed in the eighth metal layer that passes through the center of subgrid 156 and it is the least wide of the positive power supply lines formed in the eighth metal layer that pass through subgrid 156. On each side of line 164 are wider positive power supply lines, and these positive power supply lines get progressively wider until the end of subgrid 156 is reached at lines 104 and 144. Similarly, line 174 is the positive power supply line formed in the ninth metal layer that passes through the center of subgrid 156 and it is the least wide of the positive power supply lines formed in the ninth metal layer that passes through subgrid 156. One each side of line 174 are wider positive power supply lines, and these positive power supply lines get progressively wider until the end of subgrid 156 is reached at lines 108 and 130. Not shown are the negative power supply lines and the signal lines. The negative power supply lines are in the same arrangement as the positive power supply lines and so that they get progressively less wide as the center is approached. The negative power supply lines and the positive power supply lines run preferably run next to each other as power supply pairs. At least some signal lines, however, could run between paired positive and negative power supply lines.

Additional subgrids 180, 182, and 184 are also shown in FIG. 3. Each of these subgrids 180-184 have the same characteristic of the lines within the subgrid getting progressively less wide as the center of the subgrid is approached. For example for the ninth metal layer, subgrid 180 has lines 186 and 188 of descending width from line 130 to center line 190 in the middle which is the line of subgrid 180 that is the least wide. Lines 190 and 192 are of ascending width from center line 190 as the perimeter is reached at line 132. Shown in subgrids 156, 180, 182, and 184 of FIG. 3 is a single line being in the center of each subgrid but a pair of positive power supply lines could run near the center and be the least wide positive power supply lines in the subgrid. Each line runs the length of the whole grid not just a subgrid. Thus lines 108, 170-178, and 130 run not just through subgrid 156 but also through subgrid 184 without their widths substantially changing. There may be some minor changes due to variations inherent in semiconductor manufacturing. Thus each of the power lines is continuous and of substantially unchanging width across the entire grid not just subgrid 156.

The benefit of the less wide lines is that they occupy less space and provide a more even voltage distribution among the circuits under a give subgrid. In the center there is less current flow so that more resistance is needed to match the voltage drop across by the power supply lines further from the center that carry less current. By having the lines be continuous and unchanging the signal lines can have this same desirable characteristic without wasting space. Thus, a more efficient layout is possible.

In the foregoing specification, the invention has been described with reference to specific embodiments. However, one of ordinary skill in the art appreciates that various modifications and changes can be made without departing from the scope of the present invention as set forth in the claims below. For example, the number of power supply lines in a subgrid may be different than the number described. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. An integrated circuit comprising:
a substrate including active circuitry;
an interconnect overlying the substrate;
a conductive grid, the conductive grid including a plurality of conductive lines located in a first interconnect layer of the interconnect, each of the plurality of conductive lines extending across at least a majority of the integrated circuit in the first interconnect layer parallel to a first direction, each of the plurality of conductive lines are electrically coupled to each other;
wherein the conductive grid comprises:
a first conductive line of the plurality of conductive lines having a first width;
a second conductive line of the plurality of conductive lines having a second width, the second conductive line is spaced from the first conductive line in a second direction from the first conductive line, the second direction being perpendicular to the first direction, the second width being less than the first width;
a third conductive line of the plurality of conductive lines having a third width, the third conductive line is spaced from the second conductive line in the second direction from the second conductive line, the third width being greater than the second width, the second conductive line between the first and second conductive lines;
a fourth conductive line of the plurality of conductive lines having a fourth width, the fourth conductive line is spaced from the third conductive line in the second direction from the third conductive line, the fourth width being less than the third width, the third conductive line between the second and fourth conductive lines;
a fifth conductive line of the plurality of conductive lines having a fifth width, the fifth conductive line is spaced from the fourth conductive line in the second direction from the fourth conductive line, the fifth width being greater than the fourth width, the fourth conductive line between the third and fifth conductive lines.

2. The integrated circuit of claim 1 wherein the first width, the third width, and the fifth width are the same width.

3. The integrated circuit of claim 1 wherein the second width and the fourth width are the same width.

4. The integrated circuit of claim 1 wherein:
the first width, the third width, and the fifth width are the same width;
the second width and the fourth width are the same width.

5. The integrated circuit of claim 1 wherein:
a sixth conductive line of the plurality of conductive lines having a sixth width, the sixth conductive line is spaced from the fifth conductive line in the second direction from the fifth conductive line, the sixth width being less than the fifth width, the fifth conductive line between the fourth and sixth conductive lines;
a seventh conductive line of the plurality of conductive lines having a seventh width, the seventh conductive line is spaced from the sixth conductive line in the second direction from the sixth conductive line, the seventh width being greater than the sixth width, the sixth conductive line between the fifth and seventh conductive lines.

6. The integrated circuit of claim 5 wherein:
the first width, the third width, the fifth width, and seventh are the same width;
the second width, the fourth width, and sixth width are the same width.

7. The integrated circuit of claim 1 wherein:
a sixth conductive line of the plurality of conductive lines having a sixth width, the sixth conductive line is located between the first conductive line and the second conductive line, the sixth width being less than the first width and greater than the second width;
a seventh conductive line of the plurality of conductive lines having a seventh width, the seventh conductive line is located between the second conductive line and the third conductive line, the seventh width being greater than the second width and less than the third width;
an eighth conductive line of the plurality of conductive lines having an eighth width, the eighth conductive line is located between the third conductive line and the fourth conductive line, the eighth width being less than the third width and greater than the fourth width;
a ninth conductive line of the plurality of conductive lines having a ninth width, the ninth conductive line is located between the fourth conductive line and the fifth conductive line, the ninth width being greater than the fourth width and less than the fifth width.

8. The integrated circuit of claim 7 wherein:
a tenth conductive line of the plurality of conductive lines having a tenth width, the tenth conductive line is located between the sixth conductive line and the second conductive line, the tenth width being less than the sixth width and greater than the second width;
an eleventh conductive line of the plurality of conductive lines having an eleventh width, the eleventh conductive line is located between the second conductive line and the seventh conductive line, the eleventh width being greater than the second width and less than the seventh width;
a twelfth conductive line of the plurality of conductive lines having an twelfth width, the twelfth conductive line is located between the eighth conductive line and the fourth conductive line, the twelfth width being less than the eighth width and greater than the fourth width;
a thirteenth conductive line of the plurality of conductive lines having a thirteenth width, the thirteenth conductive line is located between the fourth conductive line and the ninth conductive line, the thirteenth width being greater than the fourth width and less than the ninth width.

9. The integrated circuit of claim 8 wherein the tenth width, the eleventh width, the twelfth width, and the thirteenth width are the same width.

10. The integrated circuit of claim 8 wherein:
a fourteenth conductive line of the plurality of conductive lines having a fourteenth width, the fourteenth conductive line is located between the tenth conductive line and the second conductive line, the fourteenth width being less than the tenth width and greater than the second width;
an fifteenth conductive line of the plurality of conductive lines having an fifteenth width, the fifteenth conductive line is located between the second conductive line and the eleventh conductive line, the fifteenth width being greater than the second width and less than the eleventh width;
a sixteenth conductive line of the plurality of conductive lines having an sixteenth width, the sixteenth conductive line is located between the twelfth conductive line and the fourth conductive line, the sixteenth width being less than the twelfth width and greater than the fourth width;
a seventeenth conductive line of the plurality of conductive lines having a seventeenth width, the seventeenth conductive line is located between the fourth conductive line and the thirteenth conductive line, the seventeenth width being greater than the fourth width and less than the thirteenth width.

11. The integrated circuit of claim 7 wherein the sixth width, the seventh width, the eighth width, and the ninth width are the same width.

12. The integrate circuit of claim 1 wherein:
the conductive grid includes a second plurality of conductive lines located in a second interconnect layer of the interconnect, each of the second plurality of conductive lines running across at least a majority of the integrated circuit in the second interconnect layer parallel to the second direction, each of the second plurality of conductive lines are electrically coupled to each other and to each of the plurality of conductive lines;
a sixth conductive line of the second plurality of conductive lines has a sixth width;
a seventh conductive line of the plurality of conductive lines having a seventh width, the seventh conductive line is spaced from the sixth conductive line in a first direction from the sixth conductive line, the seventh width being less than the sixth width;
an eighth conductive line of the plurality of conductive lines having an eighth width, the eighth conductive line is spaced from the seventh conductive line in the first direction from the seventh conductive line, the eighth width being greater than the seventh width, the eighth line between the seventh and fifth conductive lines, the seventh conductive line between the eighth and sixth conductive lines;
a ninth conductive line of the plurality of conductive lines having a ninth width, the ninth conductive line is spaced from the eighth conductive line in the first direction from the eighth conductive line, the ninth width being less than the eighth width, the eighth conductive line between the ninth and seventh lines;
a tenth conductive line of the plurality of conductive lines having a tenth width, the tenth conductive line is spaced from the ninth conductive line in the first direction from the ninth conductive line, the tenth width being greater than the ninth width, wherein the ninth conductive line is between the eighth and the tenth conductive lines.

13. The integrated circuit of claim 12 wherein:
the sixth width, the eighth width, and the tenth width are the same width;
the seventh width and the ninth width are the same width.

14. The integrated circuit of claim 12 wherein:
the first interconnect layer is above the second interconnect layer;
a via is located at each location wherein a conductive line of the plurality crosses over a conductive line of the second plurality with a top part of the via in electrical contact with the conductive line of the plurality and the bottom part of the via in electrical contact with the conductive line of the second plurality.

15. The integrated circuit of claim 1 further comprising:
a plurality of conductive terminals overlying the interconnect, the plurality of conductive terminal being positioned at a first pitch in the second direction, wherein a distance between a center of the first conductive line and a center of the third conductive line is equal to the first pitch, wherein a distance between a center of the third conductive line and a fifth conductive line is equal to the first pitch.

16. The integrated circuit of claim 1 wherein a center of each conductive line of the plurality is located at a first distance from a center of an immediately adjacent conductive line of the plurality.

17. The integrated circuit of claim 1 further comprising:
a first signal line including at least a portion located between the first conductive line and the second conductive line in the interconnect layer.

18. The integrated circuit of claim 1 wherein each of the plurality of conductive lines extends across at least a substantial majority of the integrated circuit in the first interconnect layer parallel to the first direction.

19. The integrated circuit of claim 1 wherein each of the conductive lines of the plurality have a uniform width along at least a substantial majority of the integrated circuit.

20. The integrated circuit of claim 1 wherein the conductive grid is biased to provide a non ground voltage.

21. The integrated circuit of claim 1 wherein the conductive grid is biased to provide a ground voltage.

22. The integrated circuit of claim 1 further comprising:
a second conductive grid, the second conductive grid including a second plurality of conductive lines located in the first interconnect layer of the interconnect, each of the second plurality of conductive lines extending across at least a majority of the integrated circuit in the first interconnect layer parallel to a first direction, each of the second plurality of conductive lines are electrically coupled to each other;
wherein:
a sixth conductive line of the second plurality of conductive lines has a sixth width, the sixth conductive line is located between the first conductive line and the second conductive line;
a seventh conductive line of the plurality of conductive lines having a seventh width, the seventh conductive line is located between the second conductive line and the third conductive line, the seventh width being less than the sixth width;
an eighth conductive line of the plurality of conductive lines having an eighth width, the eighth conductive line is located between the third conductive line and the fourth conductive line, the eighth width being greater than the seventh width;
a ninth conductive line of the plurality of conductive lines having a ninth width, the ninth conductive line is located between the fourth conductive line and the fifth conductive line, the ninth width being less than the eighth width;
a tenth conductive line of the plurality of conductive lines having a tenth width, the tenth conductive line is located adjacent to the fifth conductive line in the second direction from the fifth conductive line, the tenth width being greater than the ninth width;
wherein the first conductive grid is bias to provide a first voltage and the second conductive grid is biased to provide a second voltage different from the first voltage.

23. An integrated circuit comprising:
a substrate including active circuitry;
an interconnect overlying the substrate;
a conductive grid, the conductive grid including a plurality of conductive lines located in a first interconnect layer of the interconnect, each of the plurality of conductive lines extending across at least a substantial majority of the integrated circuit in the first interconnect layer parallel to a first direction, each of the plurality of conductive lines are electrically coupled to each other, each of the electrically conductive lines have a uniform width;
wherein the plurality of conductive lines includes a first group with each conductive line of the first group having a first width;
wherein the plurality of conductive lines includes a second group with each conductive line of the second group having a second width, the first width is greater than the second width;
wherein each conductive line of the second plurality is located between two lines of the first plurality;
wherein the plurality of conductive lines includes a third group with each conductive line of the third group having a third width;
wherein the third width is less than the first width and greater than the second width,
wherein each line of the second group is located between two lines of the third group with no lines of the first group located there between.

24. The integrated circuit of claim 23 wherein:
the plurality of conductive lines includes a fourth group with each conductive line of the fourth group having a fourth width,
the fourth width is less than the third width and greater than the second width,
each line of the second group is located between two lines of the fourth group with no lines of the first group located there between.

25. The integrated circuit of claim 24 wherein each line of the second group is located between two lines of the fourth group with no lines of the first group or the third group located there between.

26. The integrated circuit of claim 24 wherein:
the plurality of conductive lines includes a fifth group with each conductive line of the fifth group having a fifth width;
the fifth width is less than the fourth width and greater than the second width;
each line of the second group is located between two lines of the fifth group with no lines of the first group located there between.

27. The integrated circuit of claim 26 each line of the second group is located between two lines of the fifth group with no lines of the first group, the third group or the fourth group located there between.

28. The integrated circuit of claim 26 wherein:
the conductive grid includes a second plurality of conductive lines located in a second interconnect layer of the interconnect, each of the plurality of conductive lines extending across at least a substantial majority of the integrated circuit in a second interconnect layer parallel to a second direction, the second direction is perpendicular to the first direction, each of the second plurality of conductive lines are electrically coupled to each other and to each of the plurality of conductive lines, each of the second plurality of conductive lines have a uniform width;
the second plurality of conductive lines includes a fourth group with each conductive line of the fourth group having a fourth width;
the second plurality of conductive lines includes a fifth group with each conductive line of the fifth group having a fifth width, the fourth width is greater than the fifth width;
each conductive line of the fifth plurality is located between two lines of the fourth plurality.

29. An integrated circuit comprising:
a substrate including active circuitry;
an interconnect overlying the substrate;
a conductive grid, the conductive grid including a plurality of conductive lines located in a first interconnect layer of the interconnect, each of the plurality of conductive lines extending across at least a majority of the integrated circuit in the first interconnect layer parallel to a first direction, each of the plurality of conductive lines are electrically coupled to each other;
wherein:
a first conductive line of the plurality of conductive lines has a first width;
a second conductive line of the plurality of conductive lines having a second width, the second conductive line is spaced from the first conductive line in a second direction from the first conductive line, the second direction being perpendicular to the first direction, the second width being less than the first width;
a third conductive line of the plurality of conductive lines having a third width, the third conductive line is spaced from the second conductive line in the second direction from the second conductive line, the third width being less than the second width, the second conductive line between the first and third conductive lines;
a fourth conductive line of the plurality of conductive lines having a fourth width, the fourth conductive line is spaced from the third conductive line in the second direction from the third conductive line, the fourth width being greater than the third width, the third line between the second and fourth conductive lines;
a fifth conductive line of the plurality of conductive lines having a fifth width, the fifth conductive line is spaced from the fourth conductive line in the second direction from the fourth conductive line, the fifth width being greater than the fourth width, the fourth conductive line between the third and fifth conductive lines;
a sixth conductive line of the plurality of conductive lines having a sixth width, the sixth conductive line is spaced from the fifth conductive line in the second direction from the fifth conductive line, the sixth width being less than the fifth width, the fifth conductive line between the fourth and sixth conductive lines;
a seventh conductive line of the plurality of conductive lines having a seventh width, the seventh conductive line is spaced from the sixth conductive line in the second direction from the sixth conductive line, the seventh width being less than the sixth width, the sixth conductive line between the seventh and fifth conductive lines;
an eighth conductive line of the plurality of conductive lines having an eighth width, the eighth conductive line is spaced from the seventh conductive line in the second direction from the seventh conductive line, the eighth width being greater than the seventh width, the seventh conductive line between the eighth and sixth conductive lines;
a ninth conductive line of the plurality of conductive lines having a ninth width, the ninth conductive line is spaced from the eighth conductive line in the second direction from the eighth conductive line, the ninth width being greater than the eighth width, the eighth conductive line between the seventh and ninth conductive lines.
